(19) United States
(12) Patent Application Publication
(10) Pub. No.: US 2026/0081096 A1
(43) Pub. Date: Mar. 19, 2026

(54) ELECTRONIC COMPONENT

(71) Applicant: NuFlare Technology, Inc., Yokohama-shi (JP)

(72) Inventors: Tomohiro SAITO, Yokohama-shi (JP); Hideo INOUE, Miura-gun (JP)

(73) Assignee: NuFlare Technology, Inc., Yokohama-shi (JP)

(21) Appl. No.: 19/281,824

(22) Filed: Jul. 28, 2025

(30) Foreign Application Priority Data
Sep. 18, 2024 (JP) 2024-160719

(51) Int. Cl. H01J 37/147; H01J 37/30

(52) U.S. Cl. CPC H01J 37/1472; H01J 37/3007; H01J 2237/151

(57) ABSTRACT

An electronic component of an embodiment includes an electrode array unit including a substrate having a plurality of through holes, each of a plurality of charged particle beams passes through each of the plurality of through holes; and a plurality of electrode pairs provided in each of the plurality of through holes, wherein each of the plurality of electrode pairs includes a first electrode and a second electrode, the first electrode and the second electrode both include an arc-shaped portion and an end portion, the arc-shaped portion of the first electrode and the second electrode surround a central portion of each of the plurality of through holes, and the end portion of the first electrode and the second electrode face each other.

### CROSS-REFERENCE TO RELATED APPLICATION

This application is based upon and claims the benefit of priority from Japanese Patent Applications No. 2024-160719, filed on Sep. 18, 2024, the entire contents of which are incorporated herein by reference.

### FIELD OF THE INVENTION

The present invention relates to electronic components.

### BACKGROUND OF THE INVENTION

Lithography technology is a process technology responsible for the advancement of miniaturization of semiconductor devices. Lithography technology is an extremely important process technology. In recent years, with the increase in integration and capacity of large-scale integrated circuits (LSI), the circuit line width required for semiconductor devices has been miniaturized year by year. The electron beam writing technology has an inherently excellent resolution. Therefore, using the electron beam, mask patterns are written onto mask blanks.

A multi-electron beam drawing apparatus can significantly improve throughput compared to using a single electron beam. For example, in the writing apparatus using the multiple beams, the multiple beams are formed by passing an electron-beam emitted from an electron gun through a shaping aperture having a plurality of holes. The respective electron beams constituting the multiple beams are subjected to blanking control by a blanking aperture array. The electron beam that is not deflected by the blanking aperture array is irradiated onto a target object such as a mask blank. On the other hand, the electron beam deflected by the blanking aperture array is shielded (blanked).

The blanking aperture array has through holes through which each electron beam passes. An electrode pair is provided around the through hole. An electric field (deflection electric field) for deflecting the electron beam is generated between the electrode pair.

### SUMMARY OF THE INVENTION

An electronic component of an embodiment includes an electrode array unit including a substrate having a plurality of through holes, each of a plurality of charged particle beams passes through each of the plurality of through holes; and a plurality of electrode pairs provided in each of the plurality of through holes, wherein each of the plurality of electrode pairs includes a first electrode and a second electrode, the first electrode and the second electrode both include an arc-shaped portion and an end portion, the arc-shaped portion of the first electrode and the second electrode surround a central portion of each of the plurality of through holes, and the end portion of the first electrode and the second electrode face each other.

### BRIEF DESCRIPTION OF THE DRAWINGS

FIG. 1 is a schematic cross-sectional view of the electron beam writing apparatus of a first embodiment.

FIGS. 2A-B are schematic views of a main part of the electronic component of the first embodiment.

FIG. 3 is a schematic cross-sectional view showing a manufacturing method of the electronic component of the first embodiment.

FIG. 4 is a schematic cross-sectional view showing a manufacturing method of the electronic component of the first embodiment.

FIG. 5 is a schematic cross-sectional view showing a manufacturing method of the electronic component of the first embodiment.

FIG. 6 is a schematic cross-sectional view showing a manufacturing method of the electronic component of the first embodiment.

FIG. 7 is a schematic cross-sectional view showing a manufacturing method of the electronic component of the first embodiment.

FIG. 8 is a schematic cross-sectional view showing a manufacturing method of the electronic component of the first embodiment.

FIG. 9 is a schematic top view of the main part of the electronic component in the comparative embodiment of the first embodiment.

FIG. 10 is a schematic cross-sectional view showing a part of the manufacturing method of the electronic component in a comparative form of the first embodiment.

FIG. 11 is a schematic top view of the main part of the electronic component of the second embodiment.

FIG. 12 is a schematic cross-sectional view of the main part of the electronic component of the third embodiment.

### DETAILED DESCRIPTION OF THE EMBODIMENTS

Hereinafter, embodiments will be described with reference to the drawings. In the drawings, the same or similar parts are denoted by the same or similar reference numerals.

In this specification, identical or similar components may be assigned the same reference numerals, and redundant descriptions may be omitted.

In this specification, to indicate the positional relationship of parts, the upward direction in the drawings is described as “up” and the downward direction as “down”. In this specification, the concepts of “upper” and “lower” do not necessarily refer to the direction of gravity.

Hereinafter, a configuration using an electron beam will be described as an exemplary the charged particle beam. However, the charged particle beam is not limited to an electron beam. The charged particle beam may also be an ion beam.

### First Embodiment

The electronic component of the present embodiment includes an electrode array unit including: a substrate having a plurality of through holes, each of a plurality of charged particle beams passes through each of the plurality of through holes; and a plurality of electrode pairs provided in each of the plurality of through holes, wherein each of the plurality of electrode pairs includes a first electrode and a second electrode, the first electrode and the second electrode both include an arc-shaped portion and an end portion, the arc-shaped portion of the first electrode and the second electrode surround a central portion of each of the plurality of through holes, and the end portion of the first electrode and the second electrode face each other.

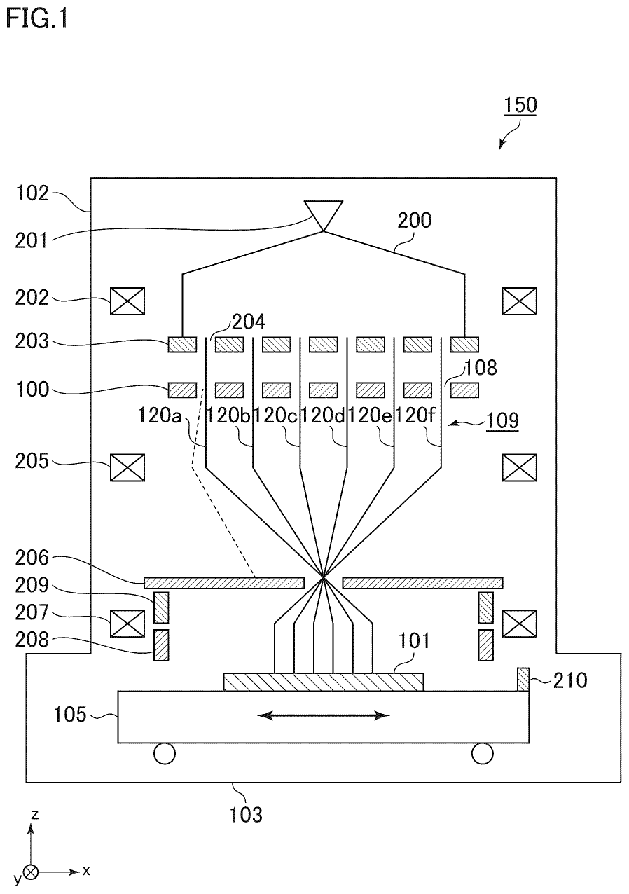

FIG. 1 is a schematic cross-sectional view of the electron beam writing apparatus 150 of the present embodiment.

The electronic component 100 of the present embodiment is used, for example, as the blanking aperture array (deflector) of the electron beam writing apparatus 150. Furthermore, the applications of electronic component 100 are not limited to this.

The electron beam writing apparatus 150 includes an electron optical column 102 (a multi-electron beam column) and a writing chamber 103.

Disposed within the electron optical column 102 are the electron gun 201, the illumination lens 202, the shaping aperture array 203, the electronic component 100, the reduction lens 205, the limiting aperture member 206, the objective lens 207, the main deflector 208, and the secondary deflector 209.

The electron gun 201 emits the electron beam 200. Additionally, the electron gun 201 is an example of an irradiation source.

Here, an x-axis, a y-axis intersecting perpendicularly to the x-axis, and a z-axis intersecting perpendicularly to the x-axis and y-axis, are defined. The electron gun 201 is assumed to emit the electron beam 200 in the direction opposite to the z-axis. Additionally, assume that target object 101 is positioned within a plane parallel to the xy-plane.

The entire shaping aperture array 203 is substantially vertically illuminated with the electron beam 200 emitted from the electron gun 201 by the electromagnetic lens 202. The electron beam 200 passes through the openings of the shaping aperture array 203, and multiple beams 109 are formed. The multiple beams 109 have electron beams 120a, 120b, 120c, 120d, 120e, and 120f. The shape of each electron beam 120 reflects the shape of the opening of the shaping aperture array 203. The shape of each electron beam 120 is, for example, rectangular. Here, as illustrated in FIG. 1, the openings 204 of the shaping aperture array 203 are six in number. However, the number of openings 204 in the shaping aperture array 203 is not limited to six. The number of the multiple beams 109 formed by the shaping aperture array 203, as illustrated in FIG. 1, is six. However, the number of the multiple beams 109 formed by the shaping aperture array 203 is not limited to six.

The electronic component 100 is provided below the shaping aperture array 203. The position of the electron beam 120 deflected by the electronic component 100 deviates from the central aperture of the limiting aperture plate member 206. The electron beam 120 deflected by the electronic component 100 is shielded by the limiting aperture member 206. On the other hand, the electron beam 120 that is not deflected by the electronic component 100 passes through the hole at the center of the limiting aperture member 206. In this way, the on/off of the electron beam is controlled. Here, the number of openings 108 of the electronic component 100 illustrated in FIG. 1 is six. However, the number of openings 108 in the electronic component 100 is not limited to six.

The focus of the electron beam 120 passing through the limiting aperture member 206 is properly adjusted by the objective lens 207. Subsequently, the electron beam 120 passing through the limiting aperture member 206 becomes a pattern image with the desired reduction ratio. Subsequently, the electron beam 120 passing through the limiting aperture member 206 is collectively deflected by the main deflector 208 and the secondary deflector 209. Subsequently, the electron beam 120 passing through the limiting aperture member 206 is irradiated at each irradiation position on the target object 101 placed on the XY stage 105. Further, a mirror 210 for measuring the position of the XY stage 105 is disposed on the XY stage 105.

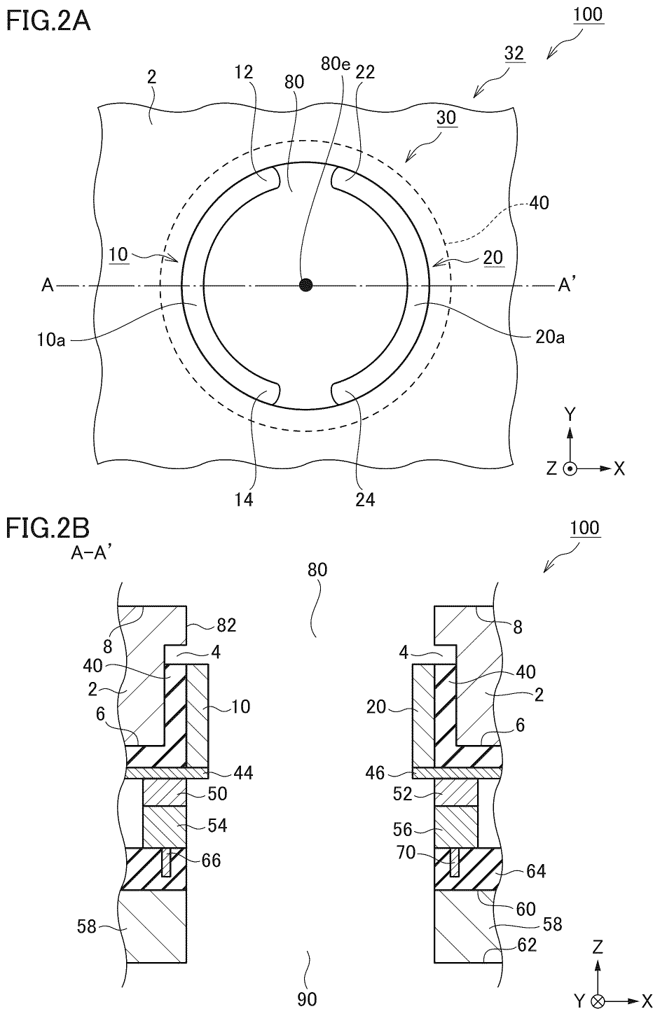

FIGS. 2A-B are the schematic views of the main part of the electronic component 100 of the present embodiment. FIG. 2A is a schematic top view of the main part of the electronic component 100 of the present embodiment. FIG. 2B is a schematic cross-sectional view of the electronic component 100, which is a main part of the present embodiment, in the A-A′ cross-section shown in FIG. 2A.

The first substrate 2 (an example of a substrate) is, for example, a semiconductor substrate. The first substrate 2 is, for example, a Si (silicon) substrate. However, the first substrate 2 is not limited to a semiconductor substrate. For example, as the first substrate 2, other substrates such as an insulating substrate can also be preferably used. Here, the insulating substrate is, for example, a ceramic substrate. Additionally, the insulating substrate is, for example, a glass epoxy substrate containing glass fibers and epoxy resin.

The first substrate 2 has a first substrate surface 6 and a second substrate surface 8 opposite to the first substrate surface 6. In FIG. 2B, the first substrate surface 6 is illustrated as being positioned below the second substrate surface 8.

The first substrate 2 has a plurality of first through holes 80 (an example of through holes). Each of the electron beams 120 included in the multiple beams 109 passes through each of the plurality of first through holes 80.

In the electronic component 100 shown in FIGS. 2A-B, the shape of the plurality of first through holes 80 in a plane parallel to the xy plane has an arc-shaped portion, for example, circular. However, the shape of the plurality of first through holes 80 in a plane parallel to the xy plane is not limited to a circular shape.

The plurality of electrode pairs 30 are provided in each of the plurality of first through holes 80. Each of the plurality of electrode pairs 30 has a first electrode 10 and a second electrode 20.

The first electrode 10 includes an arc-shaped portion 10a arranged to surround the central portion 80e of the corresponding first through hole 80 (the first through hole 80 in which the first electrode 10 is provided). The second electrode 20 includes an arc-shaped portion 20a arranged to surround the central portion 80e of the corresponding first through hole 80 (the first through hole 80 in which the second electrode 20 is provided). Then, the end 12 of the first electrode 10 and the end 22 of the second electrode 20 are arranged to face each other. Also, the end 14 of the first electrode 10 and the end 24 of the second electrode 20 are arranged to face each other.

The electrode array unit 32 (electrode array) includes the first substrate 2 having a plurality of first through holes 80 and a plurality of electrode pairs 30.

The first insulating film (an example of insulating film) 40 is provided between the first electrode 10 and the first substrate 2, and between the second electrode 20 and the first substrate 2, inside each of the plurality of first through holes 80. The first electrode 10 and the second electrode 20 are provided in the first through hole 80 via the insulating film 40. Furthermore, the insulating film 40 is provided in contact with the first substrate surface 6. The insulating film 40 provided inside each of the plurality of first through holes 80 is continuous with the insulating film 40 provided in contact with the first substrate surface 6. However, the shape of the insulating film 40 is not limited to the above. The insulating film 40 includes, for example, SiOx (silicon oxide).

The circuit board (an example of second substrate) 58 has a third substrate surface 60 and a fourth substrate surface 62. The third substrate surface 60 is provided facing the first substrate surface 6. The circuit board 58 is, for example, a silicon substrate. However, the circuit board 58 is not limited to a silicon substrate. The circuit board 58 has a plurality of second through holes 90.

The pair of the first through hole 80 and the second through hole 90 corresponds to the opening 108 (FIG. 1). Each of the first through holes 80 is provided above each of the second through holes 90.

Incidentally, in FIGS. 2A-B, one of the plurality of first through holes 80 of the first substrate 2 is shown. Also, in FIG. 2, one of the plurality of second through holes 90 of the circuit board 58 is shown.

The second insulating film 64 is provided on the third substrate surface 60 of the circuit board 58. The second insulating film 64 includes, for example, silicon oxide. However, the second insulating film 64 may be a laminated film including a silicon oxide-containing film and a film containing SiNx (silicon nitride).

Each of the plurality of first conductive films 44 is provided under the first electrode 10 and under the insulating film 40 in contact with the first electrode 10, respectively. Each of the plurality of first conductive films 44 is electrically and continuously connected to the first electrode 10, respectively.

Each of the plurality of first bonding electrodes 50 is provided under the plurality of first conductive films 44, respectively. Each of the plurality of first bonding electrodes 50 is electrically connected to the plurality of first conductive films 44, respectively. Each of the plurality of first bonding electrodes 50 is provided on the first substrate surface 6 via the insulating film 40, respectively.

Each of the plurality of second conductive films 46 is provided under the second electrode 20 and under the insulating film 40 in contact with the second electrode 20, respectively. Each of the plurality of second conductive films 46 is electrically and continuously connected to the second electrode 20, respectively.

Each of the plurality of second bonding electrodes 52 is provided under the plurality of second conductive films 46, respectively. Each of the plurality of second bonding electrodes 52 is electrically connected to the plurality of second conductive films 46, respectively. Each of the plurality of second bonding electrodes 52 is provided on the first substrate surface 6 via the insulating film 40, respectively.

The plurality of third bonding electrodes 54 are provided under the plurality of first bonding electrodes 50, respectively. Each of the plurality of third bonding electrodes 54 is electrically connected to the plurality of first bonding electrodes 50, respectively. Each of the plurality of third bonding electrodes 54 is provided on the third substrate surface 60 via the second insulating film 64, respectively.

The plurality of fourth bonding electrodes 56 are provided under the plurality of second bonding electrodes 52, respectively. Each of the plurality of fourth bonding electrodes 56 is electrically connected to the plurality of second bonding electrodes 52, respectively. The plurality of fourth bonding electrodes 56 are provided on the third substrate surface 60 via the second insulating film 64, respectively.

The length in the z-direction of each of the plurality of first bonding electrodes 50, the length in the z-direction of the plurality of second bonding electrodes 52, the length in the z-direction of the plurality of third bonding electrodes 54, and the length in the z-direction of the plurality of fourth bonding electrodes 56 are, for example, about 2 μm.

In the vicinity of the second substrate surface 8, the side surfaces of the plurality of first through holes 80 may have exposed portion 82 (a portion of the first substrate 2 that is exposed). Incidentally, the side surfaces of the plurality of first through holes 80 may not have the exposed portion 82. When the first substrate 2 is a semiconductor substrate such as a silicon (Si) substrate, it is preferable that the side surfaces of the plurality of first through holes 80 are exposed and have an exposed portion 82 (a portion of the first substrate 2 that is exposed). For example, compared to the case where the insulating film 40 is provided, by having the exposed portion 82 on the side surfaces of the plurality of first through holes 80, the portions other than the electrodes of the first through holes 80 in the vicinity of the second substrate surface 8 can be kept at the substrate potential. Thus, it has the effect of suppressing the deflection of electrons due to charging.

The first substrate 2 has a recess 4. The recess 4 is provided on the side surface of the first through hole 80 between the insulating film 40 and the second substrate surface 8 so as to surround the first through hole 80. In the vicinity of the second substrate surface 8, when the side surfaces of the plurality of first through holes 80 have the exposed portion 82, the recess 4 is provided on the side surface of the first through hole 80 between the insulating film 40 and the exposed portion 82 so as to surround the first through hole 80. By providing the recess 4, the insulating film 40 can be prevented from being exposed in a plane parallel to the xy plane including the recess 4. Therefore, the deflection of electrons due to the charging of the insulating film 40 can be suppressed. Incidentally, the recess 4 may not be provided.

To apply a predetermined voltage to each of the plurality of first electrodes 10, a control circuit (not shown) is provided on the peripheral portion of the first substrate, for example, via the wiring 66 provided in the second insulating film 64, the third bonding electrode 54, the first bonding electrode 50, and the first conductive film 44. The control circuit (not shown) is, for example, a CMOS (Complementary Metal-Oxide-Semiconductor) circuit.

The wiring 70 is provided in the second insulating film 64. The wiring 70 is connected to the fourth bonding electrode 56. The wiring 70 grounds the second electrode 20 via the second conductive film 46, the second bonding electrode 52, and the fourth bonding electrode 56.

Incidentally, the first substrate 2 and the circuit board 58 may be grounded.

The plurality of first electrodes 10 and the plurality of second electrodes 20 include at least one of a metal nitride such as TiN (titanium nitride), W (tungsten), or Au (gold), or, for example, two of those metals in a laminated structure of a metal nitride and W.

The plurality of first conductive films 44, the plurality of second conductive films 46, the plurality of first bonding electrodes 50, the plurality of second bonding electrodes 52, the plurality of third bonding electrodes 54, and the plurality of fourth bonding electrodes 56, the wiring 66, and the wiring 70 include, for example, a metal such as Au, Cu (copper), TiN, or Al (aluminum).

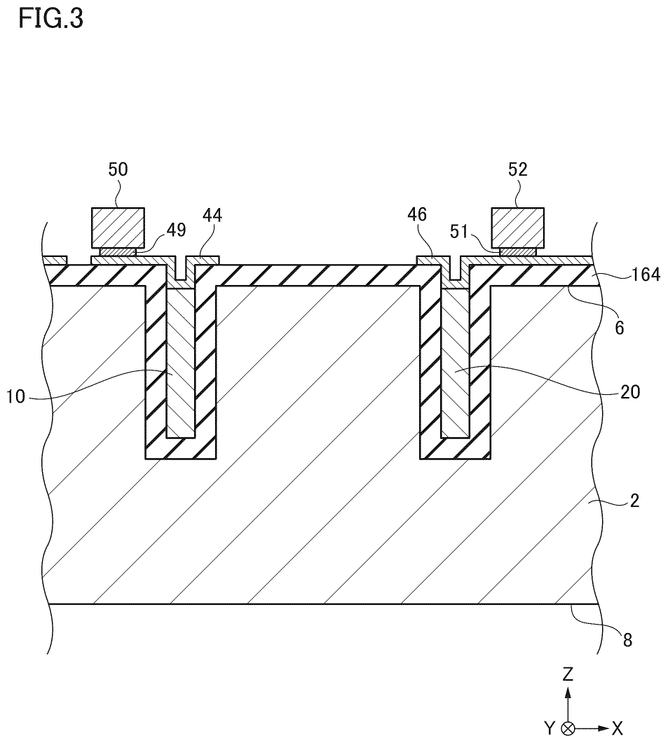

FIG. 3 to FIG. 7 are schematic cross-sectional views showing a first manufacturing method of the electronic component 100 of the present embodiment.

First, an arc-shaped groove is formed on the first substrate surface 6 of the first substrate 2, for example, by the RIE (Reactive Ion Etching) method. Next, an insulating film 164, for example, containing silicon oxide, is formed inside the groove and on the first substrate surface 6, for example, by the CVD (Chemical Vapor Deposition) method or the ALD (Atomic Layer Deposition) method. Next, on the insulating film 164, the first electrode 10 and the second electrode 20 containing metal nitrides such as TiN, W (tungsten), Au (gold), or metal nitrides, W, and Au, are formed using, for example, a CVD method or an ALD (Atomic Layer Deposition) method. Subsequently, for example, by etch back or CMP (Chemical Mechanical Polishing), the upper surfaces of the insulating film 164, the first electrode 10, and the second electrode 20 are planarized.

Next, the first conductive film 44, which contains, for example, TiN, is formed over the first electrode 10 and the insulating film 164 on the upper left of the first electrode 10. Additionally, the second conductive film 46, which contains, for example, TiN, is formed over the second electrode 20 and the insulating film 164 on the upper right of the second electrode 20. For the formation of the first conductive film 44 and the second conductive film 46, methods such as CVD, sputtering, and photolithography are used.

Next, a first bonding electrode 50 containing, for example, gold is formed on the first conductive film 44. Also, a second bonding electrode 52 containing, for example, gold is formed on the second conductive film 46. Note that the formation of the first bonding electrode 50 and the second bonding electrode 52 uses, for example, plating and photolithography methods.

Incidentally, a conductive film 49 not shown in FIG. 2B may be formed between the first conductive film 44 and the first bonding electrode 50. Also, a conductive film 51 not shown in FIG. 2B may be formed between the second conductive film 46 and the second bonding electrode 52 (FIG. 3).

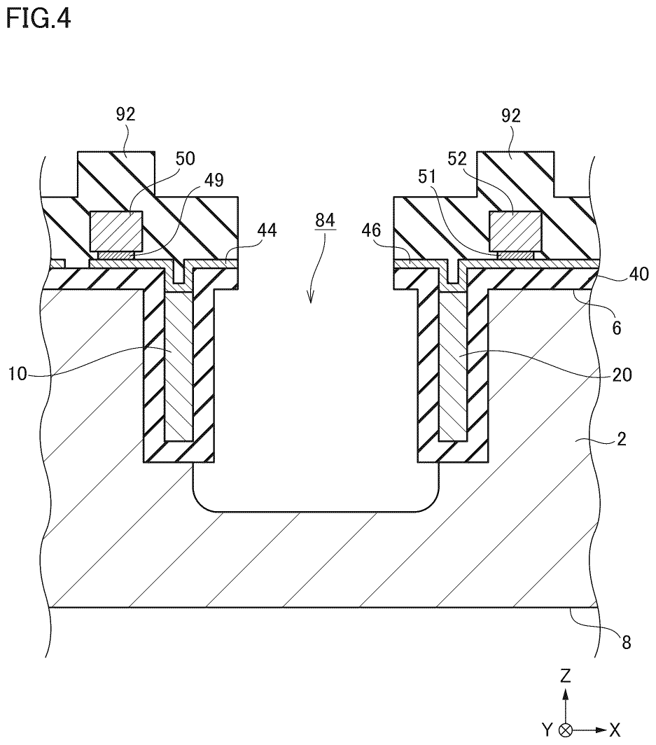

Next, using photoresist 92, a part of the first substrate 2 between the first electrode 10 and the second electrode 20 is removed by, for example, the Deep RIE (Reactive Ion Etching) method to form a hole 84. Also, this forms the insulating film 40 from the insulating film 164 (FIG. 4).

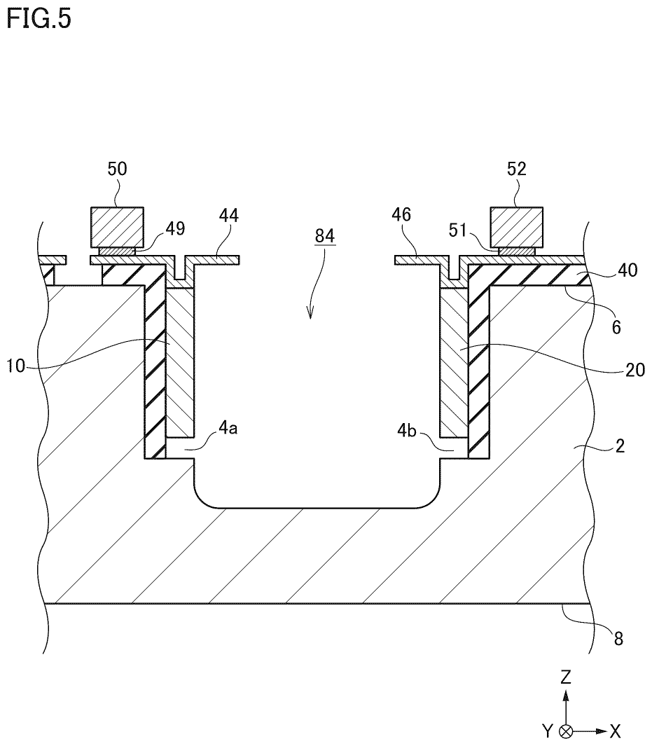

Next, the insulating film 40 provided on the right side and below the first electrode 10, and the insulating film 40 provided on the left side and below the second electrode 20 are removed by, for example, Vapor HF (vaporized hydrofluoric acid). Here, the removal of the insulating film 40 by Vapor HF is performed isotropically. Therefore, a recess 4 surrounding the hole 84 is formed on the side surface under the insulating film 40 (FIG. 5). In FIG. 5, the recess 4 is illustrated as recess 4a and recess 4b.

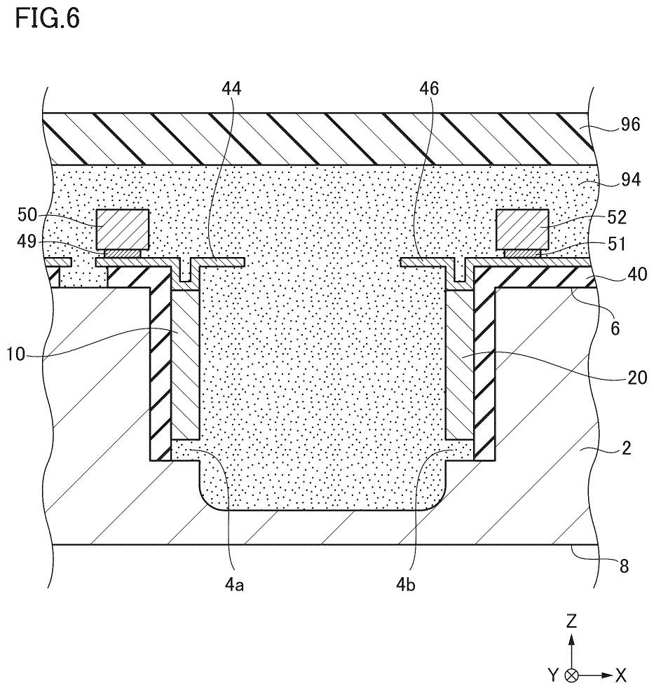

Next, an adhesive 94 is applied inside the hole 84 of the first substrate 2 and on the first substrate surface 6. Next, a substrate 96 such as a glass substrate is attached on the adhesive 94. Next, for example, the surface of the first substrate 2 opposite to the first substrate surface 6 is polished. This thins the first substrate 2. On the surface of the first substrate 2 opposite to the first substrate surface 6, a second substrate surface 8 is formed (FIG. 6).

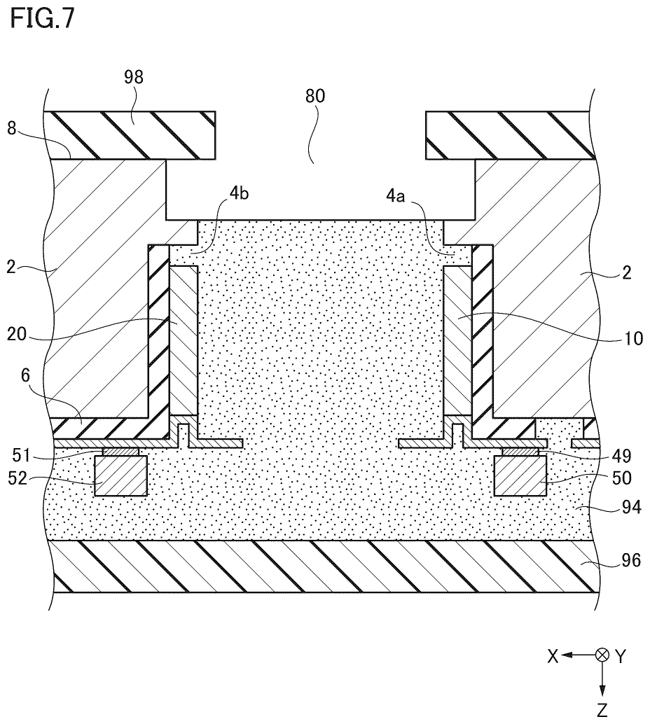

Next, using photoresist 98, for example, a part of the first substrate 2 is ground from the side of the second substrate surface 8 by, for example, the Deep RIE method to form the first through hole 80 (FIG. 7). In FIG. 7, the illustration is inverted vertically and horizontally from FIG. 6.

Next, the adhesive 94 and the substrate 96 are removed.

Next, the third bonding electrode 54 of the circuit board 58, which has the second through hole 90, the second insulating film 64, wiring 66, a control circuit not shown, wiring 70, the third bonding electrode 54, and the fourth bonding electrode 56, is joined to the first bonding electrode 50. Also, the fourth bonding electrode 56 is joined to the second bonding electrode 52. This results in the electronic component 100 of the present embodiment.

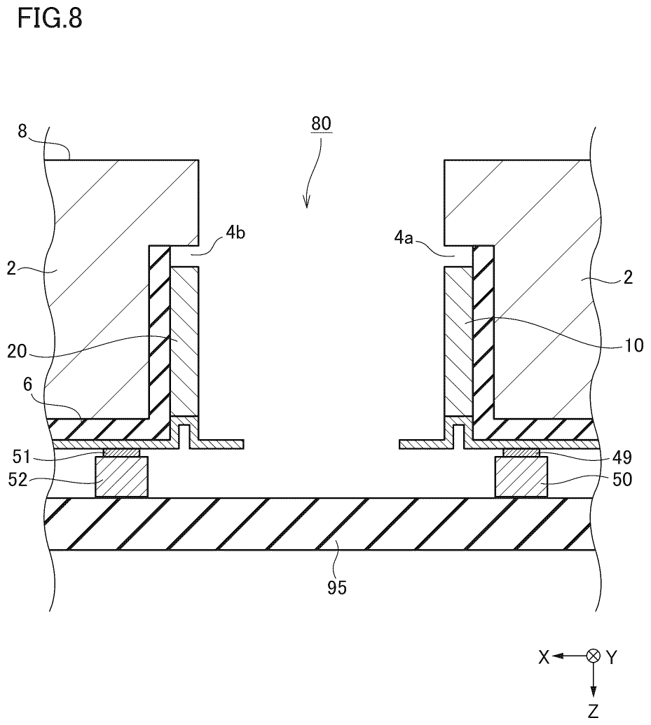

FIG. 8 is a schematic cross-sectional view showing a second manufacturing method of the electronic component 100 of the present embodiment. The manufacturing method described using FIGS. 4 to 6 is the same as the first manufacturing method.

Next, after fixing the first bonding electrode 50 and the second bonding electrode 52 with tape 95 or the like, back grinding is performed from the opposite side of the first substrate surface 6 to form the second substrate surface 8 opposite to the first substrate surface 6. Also, the first through hole 80 is formed from the hole 84. Next, dry etching is performed to remove dust generated by back grinding (FIG. 8). Next, the tape 95 is peeled off. After this, the process is the same as the first manufacturing method.

Next, the effects of the electronic component 100 of the present embodiment will be described.

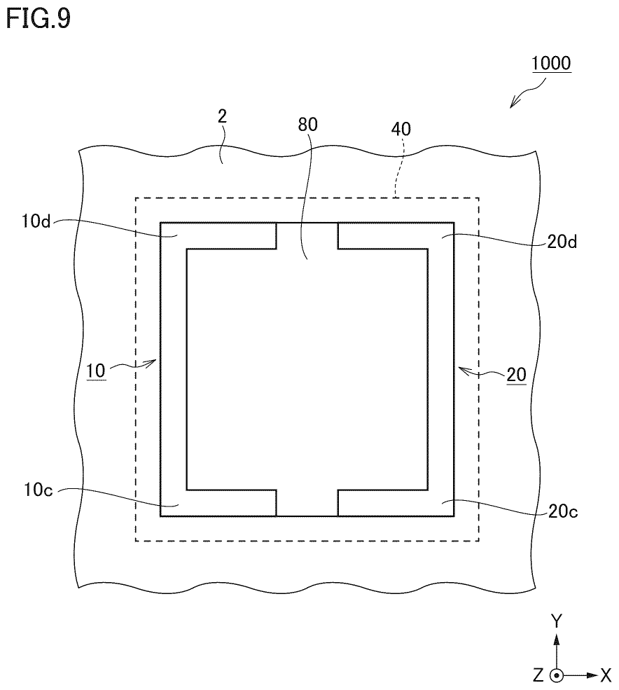

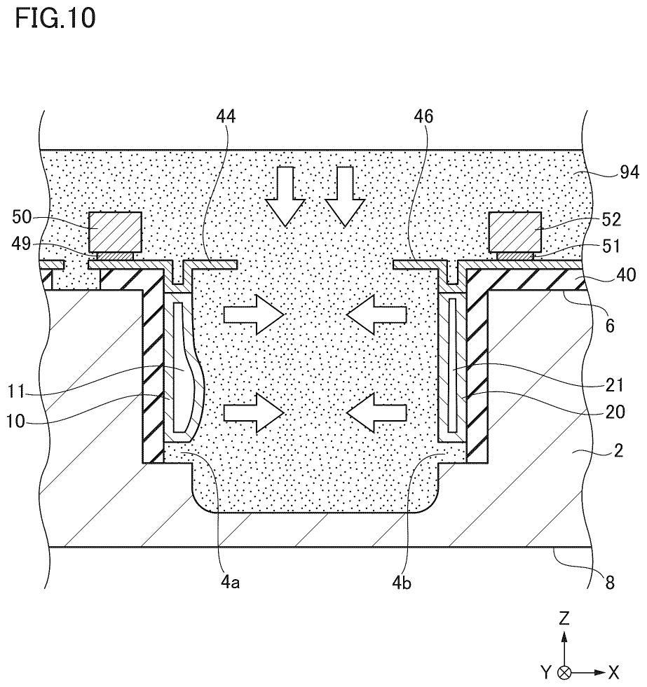

FIG. 9 is a schematic top view of the main part of an electronic component 1000 in a comparative form. The first electrode 10 and the second electrode 20 each have a U-shape facing each other. FIG. 10 is a schematic cross-sectional view showing a part of the manufacturing method of the electronic component 1000 in a comparative form.

In this case, stress applied due to the shrinkage of the adhesive 94 may cause the first electrode 10 and the second electrode 20 to break, potentially leading to problems such as the formation of cavities 11 and 21 inside (FIG. 10). Such breakage was likely to occur particularly at the corner portions 10c and 10d of the first electrode 10, and the corner portions 20c and 20d of the second electrode 20, where stress is concentrated (FIG. 9). Additionally, there was a risk that the electrode itself might deform due to the film stress of the embedded electrode material's metal. This was particularly likely to occur at the corner portions 10c and 10d of the first electrode 10, and the corner portions 20c and 20d of the second electrode 20, where stress is concentrated.

Therefore, in the electronic component 100 of the present embodiment, an electrode array unit including: a substrate having a plurality of through holes, each of a plurality of charged particle beams passes through each of the plurality of through holes; and a plurality of electrode pairs provided in each of the plurality of through holes, wherein each of the plurality of electrode pairs includes a first electrode and a second electrode, the first electrode and the second electrode both include an arc-shaped portion and an end portion, the arc-shaped portion of the first electrode and the second electrode surround a central portion of each of the plurality of through holes, and the end portion of the first electrode and the second electrode face each other.

This reduces stress concentration on the electrodes as there are no corner portions, thereby suppressing electrode breakage and the like.

Furthermore, according to the electronic component of the present embodiment, an electric field can be efficiently applied to the controlled electron beam passing through the through hole, improving controllability.

According to the electronic component of the present embodiment, it is possible to provide an electronic component that is easy to manufacture.

### Second Embodiment

The electronic component of the present embodiment differs from the electronic component of the first embodiment in that the end portion of the first electrode and the end portion of the second electrode extend away from the central portion and face each other. Here, descriptions overlapping with the first embodiment are omitted.

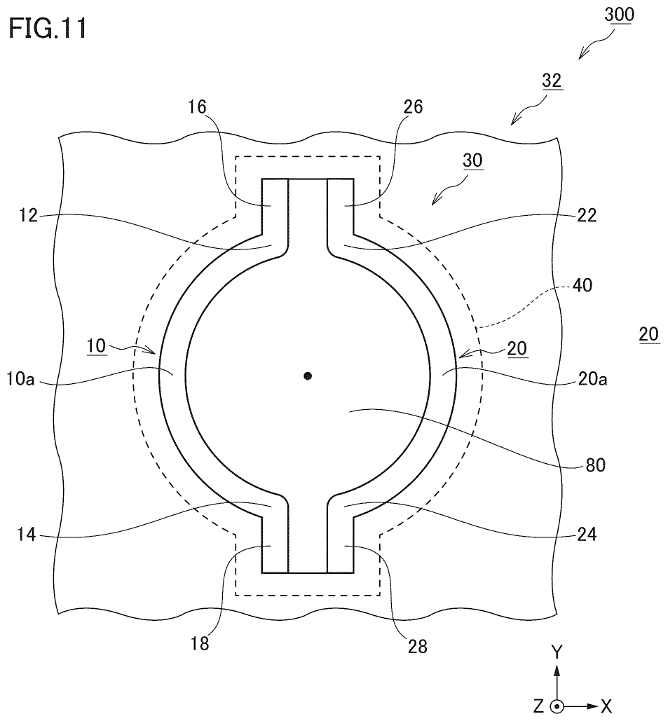

FIG. 11 is a schematic top view of the main part of the electronic component 300 of the present embodiment.

The end 12 of the first electrode 10 has a portion 16 extending in the outer peripheral direction of the arc-shaped portion 10a of the first electrode 10, away from the central portion of the first through hole 80 (in the direction outside the first through hole 80). The end 14 of the first electrode 10 has a portion 18 extending in the outer peripheral direction of the arc-shaped portion 10a of the first electrode 10, away from the central portion of the first through hole 80 (in the direction outside the first through hole 80). The end 22 of the second electrode 20 has a portion 26 extending in the outer peripheral direction of the arc-shaped portion 20a of the second electrode 20, away from the central portion of the first through hole 80 (in the direction outside the first through hole 80). The end 24 of the second electrode 20 has a portion 28 extending in the outer peripheral direction of the arc-shaped portion 20a of the second electrode 20, away from the central portion of the first through hole 80 (in the direction outside the first through hole 80). Also, the portion 16 where the end 12 of the first electrode 10 extends and the portion 26 where the end 22 of the second electrode 20 extends are extended so that portion 16 and portion 26 face each other. Also, the portion 18 where the end 14 of the first electrode 10 extends and the portion 28 where the end 24 of the second electrode 20 extends are extended so that portion 18 and portion 26 face each other.

Ends 12, 22, 14, and 24 tend to concentrate stress and are prone to breakage due to the shrinkage of adhesive 94 (FIGS. 6, 10, etc.). In the electronic component 300 of the present embodiment, by providing portions 16, 18, 26, and 28 extending in the outer peripheral direction, or extending away from the central portion and facing each other, ends 12, 22, 14, and 24 become less susceptible to the effects of the shrinkage of adhesive 94. Therefore, the breakage of the first electrode 10 and the second electrode 20 can be further suppressed.

In the electronic component of the present embodiment as well, it is possible to provide an electronic component that is easy to manufacture.

### Third Embodiment

The electronic component of the present embodiment differs from the electronic component of the first embodiment and the second embodiment in that it includes a plurality of electrode array units, one of the plurality of electrode array units is stacked with the other one of the plurality of electrode array units, and the first electrode and the second electrode of the one of the plurality of electrode array units are joined to the first electrode and the second electrode of the other one of the electrode array units via a first bonding electrode and a second bonding electrode, respectively. Here, descriptions overlapping with the first and second embodiments are omitted.

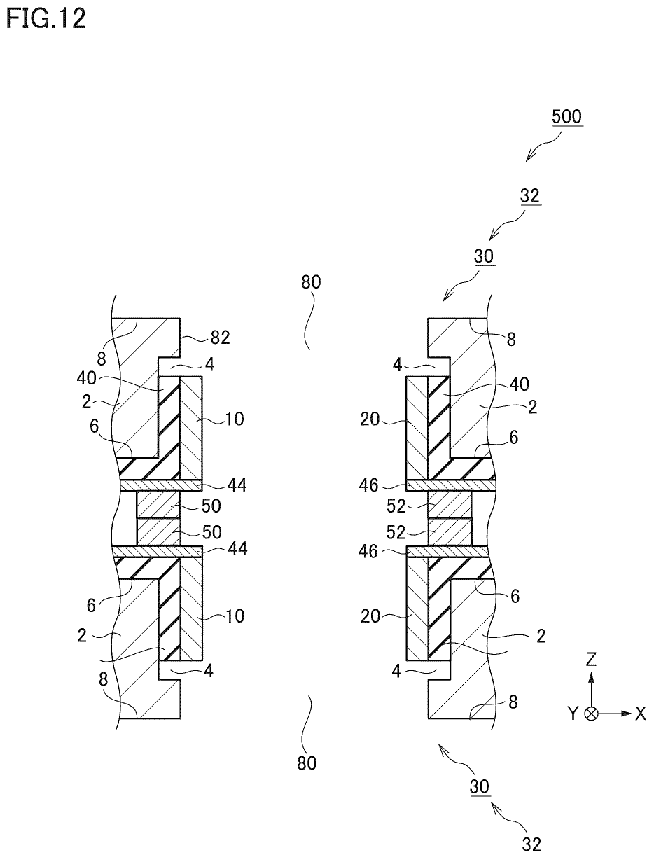

FIG. 12 is a schematic cross-sectional view of the main part of the electronic component 500 of the present embodiment.

In the electronic component 500, multiple electrode array units 32 are provided. Then, one electrode array unit 32 is stacked with other electrode array unit 32 in the Z-direction, and each first bonding electrode 50 (an example of a bonding electrode) and each second bonding electrode 52 (an example of a bonding electrode) are provided to face each other. Then, each first electrode 10 is joined via the first bonding electrode 50. Also, each second electrode 20 is joined via the second bonding electrode 52. This increases the length of the first electrode 10 and the second electrode 20 in the Z-direction, allowing for greater deflection of the electron beam.

In the electronic component of the present embodiment as well, it is possible to provide an electronic component that is easy to manufacture.

Note that the charged particle beam irradiation apparatus, including a multi-charged particle beam irradiation apparatus, includes a charged particle beam writing apparatus that writes mask patterns on mask blanks using a charged particle beam including an electron beam, and a charged particle beam inspection apparatus that inspects mask patterns by detecting secondary electrons generated by irradiating the mask pattern with an electron beam.

The electronic components described in the above embodiments are applicable to charged particle beam irradiation apparatuses, including multi-charged particle beam irradiation apparatuses. In other words, the electronic components described in the above embodiments are applicable not only to charged particle beam writing apparatuses, including multi-charged particle beam writing apparatuses, but also to charged particle beam inspection apparatuses, including multi-charged particle beam inspection apparatuses.

Several embodiments and examples of the present invention have been described, but these embodiments and examples are presented as examples and are not intended to limit the scope of the invention. These novel embodiments can be implemented in various other forms, and various omissions, substitutions, and changes can be made without departing from the gist of the invention. These embodiments and their variations are included within the scope and gist of the invention, as well as within the scope of the invention described in the claims and their equivalents.

The above embodiments can be summarized in the following technical proposals.

### (Technical Proposal 1)

An electronic component, including:
an electrode array unit including:
   a substrate having a plurality of through holes, each of a plurality of charged particle beams passes through each of the plurality of through holes; and
   a plurality of electrode pairs provided in each of the plurality of through holes,
   wherein each of the plurality of electrode pairs includes a first electrode and a second electrode, the first electrode and the second electrode both include an arc-shaped portion and an end portion, the arc-shaped portion of the first electrode and the second electrode surround a central portion of each of the plurality of through holes, and the end portion of the first electrode and the second electrode face each other.

### (Technical Proposal 2)

The electronic component according to technical proposal 1,
wherein the end portion of the first electrode and the end portion of the second electrode extend away from the central portion and face each other.

### (Technical Proposal 3)

The electronic component according to technical proposal 1,
wherein the first electrode and the second electrode include at least one or more of a metallic nitride, W (tungsten), or Au (gold).

### (Technical Proposal 4)

The electronic component according to technical proposal 3,
wherein the metallic nitride is titanium nitride.

### (Technical Proposal 5)

The electronic component according to technical proposal 1,
wherein the first electrode and the second electrode are provided in each of the plurality of through holes via an insulating film.

### (Technical Proposal 6)

The electronic component according to technical proposal 1,
wherein the substrate is a semiconductor substrate, and a side surface of each of the plurality of through holes has an exposed portion.

### (Technical Proposal 7)

The electronic component according to technical proposal 6,
wherein the first electrode and the second electrode are provided in each of the plurality of through holes via an insulating film, and a side surface of each of the plurality of through holes has a recess between the insulating film and the exposed portion, and the recess is provided so as to surround each of the plurality of through holes.

### (Technical Proposal 8)

The electronic component according to technical proposal 1,
wherein the electronic component comprises a plurality of electrode array units, one of the plurality of electrode array units is stacked with the other one of the plurality of electrode array units, and the first electrode and the second electrode of the one of the plurality of electrode array units are joined to the first electrode and the second electrode of the other one of the electrode array units via a first bonding electrode and a second bonding electrode, respectively.

### (Technical Proposal 9)

The electronic component according to technical proposal 8,
wherein the first bonding electrode and the second bonding electrode include Au (gold) or Cu (copper).

### (Technical Proposal 10)

The electronic component according to technical proposal 2,
wherein the electronic component comprises a plurality of electrode array units, one of the plurality of electrode array units is stacked with the other one of the plurality of electrode array units, and the first electrode and the second electrode of the one of the plurality of electrode array units are joined to the first electrode and the second electrode of the other one of the electrode array units via a first bonding electrode and a second bonding electrode, respectively.

### (Technical Proposal 11)

The electronic component according to technical proposal 10,
wherein the first bonding electrode and the second bonding electrode include Au (gold) or Cu (copper).

What is claimed is:

1. An electronic component, comprising:
an electrode array unit including:
a substrate having a plurality of through holes, each of a plurality of charged particle beams passes through each of the plurality of through holes; and
a plurality of electrode pairs provided in each of the plurality of through holes,
wherein each of the plurality of electrode pairs includes a first electrode and a second electrode, the first electrode and the second electrode both include an arc-shaped portion and an end portion, the arc-shaped portion of the first electrode and the second electrode surround a central portion of each of the plurality of through holes, and the end portion of the first electrode and the second electrode face each other.

2. The electronic component according to claim 1,
wherein the end portion of the first electrode and the end portion of the second electrode extend away from the central portion and face each other.

3. The electronic component according to claim 1,
wherein the first electrode and the second electrode include at least one or more of a metallic nitride, W (tungsten), or Au (gold).

4. The electronic component according to claim 3,
wherein the metallic nitride is titanium nitride.

5. The electronic component according to claim 1,
wherein the first electrode and the second electrode are provided in each of the plurality of through holes via an insulating film.

6. The electronic component according to claim 1,
wherein the substrate is a semiconductor substrate, and a side surface of each of the plurality of through holes has an exposed portion.

7. The electronic component according to claim 6,
wherein the first electrode and the second electrode are provided in each of the plurality of through holes via an insulating film, and a side surface of each of the plurality of through holes has a recess between the insulating film and the exposed portion, and the recess is provided so as to surround each of the plurality of through holes.

8. The electronic component according to claim 1,
wherein the electronic component comprises a plurality of electrode array units, one of the plurality of electrode array units is stacked with the other one of the plurality of electrode array units, and the first electrode and the second electrode of the one of the plurality of electrode array units are joined to the first electrode and the second electrode of the other one of the electrode array units via a first bonding electrode and a second bonding electrode, respectively.

9. The electronic component according to claim 8,
wherein the first bonding electrode and the second bonding electrode include Au (gold) or Cu (copper).

10. The electronic component according to claim 2,
wherein the electronic component comprises a plurality of electrode array units, one of the plurality of electrode array units is stacked with the other one of the plurality of electrode array units, and the first electrode and the second electrode of the one of the plurality of electrode array units are joined to the first electrode and the second electrode of the other one of the electrode array units via a first bonding electrode and a second bonding electrode, respectively.

11. The electronic component according to claim 10,
wherein the first bonding electrode and the second bonding electrode include Au (gold) or Cu (copper).
